(19) United States
(12) Patent Application Publication
(10) Pub. No.: US 2021/0335843 A1
(43) Pub. Date: Oct. 28, 2021

(54) ARRAY SUBSTRATE AND METHOD FOR MANUFACTURING THE SAME

(71) Applicant: Wuhan China Star Optoelectronics Semiconductor Display Technology Co., Ltd., Wuhan, Hubei (CN)

(72) Inventor: Wei TAN, Wuhan (CN)

(21) Appl. No.: 16/481,072

(22) PCT Filed: Apr. 25, 2019
(86) PCT No.: PCT/CN2019/084170

§ 371 Date: Jul. 26, 2019

(30) Foreign Application Priority Data
Feb. 1, 2019 (CN) 201910104730.9

(51) Int. Cl. H01L 27/12

(52) U.S. Cl. CPC H01L 27/1248; H01L 27/1259

(57) ABSTRACT

The embodiment of the application discloses an array substrate and a method for manufacturing the same. The array substrate includes a base plate, a buffer layer, a semiconductor layer, an insulation layer and a grid layer. The insulation layer includes a first film layer and a second film layer. The density of the first film layer is greater than that of the second film layer. The first film layer with the high density is connected with a charge carrier channel, thereby ensuring the stability of the charge carrier channel and further improving the electrical stability of the array substrate.

### BACKGROUND OF THE INVENTION

### 1. Field of the Invention

The application relates to a display technical field, and more particularly to an array substrate and a method for manufacturing the same.

### 2. Description of the Prior Art

In an existing LTPS (Low Temperature Poly-silicon) product, an insulation layer between a semiconductor layer and a grid layer is usually deposited by TEOS and O2 or by SiH4 and N2O.

Because of the N element in N2O, there are many defects in an interface between the semiconductor layer and the insulation layer, which results in a large voltage drift of a flat band and the unstable electrical property of the product. Hence, TEOS and O2 are widely used to form the insulation layer in the industry, but the cost of this method is higher.

### 3. Technical Problem

In the existing LTPS product, the insulation layer between the semiconductor layer and the grid layer is usually deposited by TEOS and O2 or by SiH4 and N2O.

Because of the N element in N2O, there are many defects in an interface between the semiconductor layer and the insulation layer, which results in a large voltage drift of a flat band and the unstable electrical property of the product. Hence, TEOS and O2 are widely used to form the insulation layer in the industry, but the cost of this method is higher.

### BRIEF SUMMARY OF THE INVENTION

### Technical Solutions

An object of the present invention is to provide an array substrate and a method for manufacturing the same to improve the stability of the array substrate.

The present application further provides an array substrate, including: a base plate, a buffer layer, a semiconductor layer, an insulation layer and a grid layer; the buffer layer being disposed on the base plate; the semiconductor layer being disposed on the buffer layer; the insulation layer covering the buffer layer and the semiconductor layer; and the grid layer being disposed on the insulation layer; wherein, the semiconductor layer includes a charge carrier channel on one surface of the semiconductor layer facing the insulation layer; the insulation layer including a first film layer and a second film layer; the first film layer covering the semiconductor layer and the buffer layer; the second film layer covering the first film layer; the grid layer being located on the second film layer; a density of the first film layer being greater than that of the second film layer; the charge carrier channel being connected with the first film layer.

In the array substrate provided by one embodiment of the present application, a thickness of the first film layer is between 100 Å-200 Å.

In the array substrate provided by one embodiment of the present application, a deposition rate of the first film layer is less than 15 Å/s.

In the array substrate provided by one embodiment of the present application, the first film layer includes a first silicon oxide film.

In the array substrate provided by one embodiment of the present application, a thickness of the second film layer is between 1200 Å-1500 Å.

In the array substrate provided by one embodiment of the present application, a deposition rate of the second film layer is greater than or equal to 15 Å/s.

In the array substrate provided by one embodiment of the present application, the second film layer includes a second silicon oxide film.

In the array substrate provided by one embodiment of the present application, a thickness of the charge carrier channel is between 200 Å-500 Å.

In the array substrate provided by one embodiment of the present application, a material of the buffer layer includes silicon oxide, and a thickness of the buffer layer is between 2000 Å-3000 Å.

The present application further provides a method for manufacturing an array substrate. The method including:

providing a base plate, and depositing a buffer layer and a semiconductor layer on the base plate in turn;

disposing a charge carrier channel on the semiconductor layer;

depositing an insulation layer on the semiconductor layer, including

depositing a first film layer on the semiconductor layer, which covers the semiconductor layer and the buffer layer; and

depositing a second film layer on the first film layer, wherein, a density of the first film layer being greater than that of the second film layer;

depositing a grid layer on the insulation layer.

In the method for manufacturing the array substrate provided by one embodiment of the present application, a thickness of the first film layer is between 100 Å-200 Å.

In the method for manufacturing the array substrate provided by one embodiment of the present application, a deposition rate of the first film layer is less than 15 Å/s.

In the method for manufacturing the array substrate provided by one embodiment of the present application, the first film layer includes a first silicon oxide film.

In the method for manufacturing the array substrate provided by one embodiment of the present application, a thickness of the second film layer is between 1200 Å-1500 Å.

In the method for manufacturing the array substrate provided by one embodiment of the present application, a deposition rate of the second film layer is greater than or equal to 15 Å/s.

In the method for manufacturing the array substrate provided by one embodiment of the present application, the second film layer includes a second silicon oxide film.

In the method for manufacturing the array substrate provided by one embodiment of the present application, a thickness of the charge carrier channel is between 200 Å-500 Å.

In the method for manufacturing the array substrate provided by one embodiment of the present application, a material of the buffer layer includes silicon oxide, and a thickness of the buffer layer is between 2000 Å-3000 Å.

### Beneficial Effect

The array substrate provided by one embodiment of the application includes a base plate, a buffer layer, a semiconductor layer, an insulation layer and a grid layer. The insulation layer includes a first film layer and a second film layer. The density of the first film layer is greater than that of the second film layer. The charge carrier channel is connected with the first film layer with the high density, thereby ensuring the stability of the charge carrier channel and further improving the electrical stability of the array substrate.

### BRIEF DESCRIPTION OF THE DRAWINGS

For more clearly illustrating the technical scheme in the embodiment of the present application, the following text will briefly introduce the accompanying drawings used in the embodiment. It is obvious that the accompanying drawings in the following description are only some embodiments of the present application. For the technical personnel of the field, other drawings can also be obtained from these drawings without paying creative work.

FIG. 1 is a structure schematic view of an array substrate provided by one embodiment of the application; and

FIG. 2 is a flow chart of a method for manufacturing an array substrate in one embodiment of the application.

### DETAILED DESCRIPTION OF THE PREFERRED EMBODIMENTS

The following text will clearly and completely describe embodiments of the present invention with reference to the accompanying drawings. Obviously, the described embodiments are only part of the embodiments of the application, not all of the embodiments. Based on the embodiments of the application, all of the other embodiments acquired by those skilled in the art without creative labor will fall within the scope of the present application.

The embodiment of the application provides an array substrate and a method for manufacturing the same, which are described in detail below.

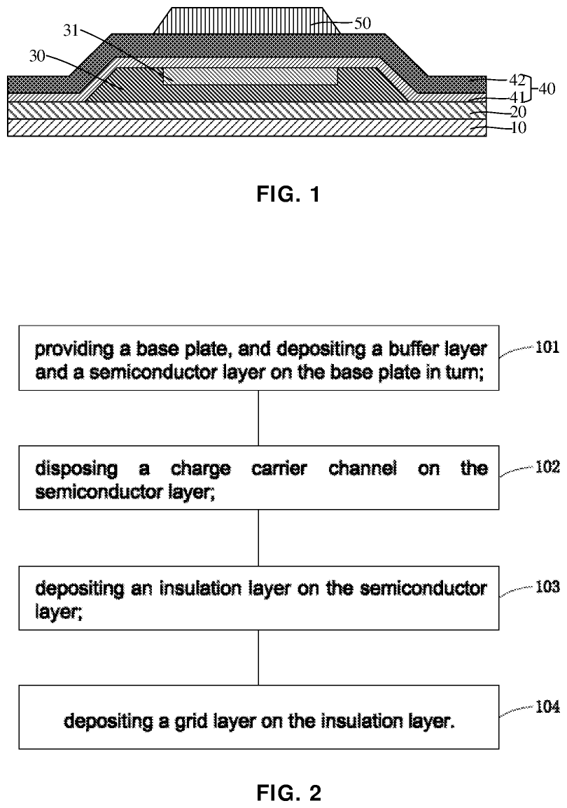

Please refer to FIG. 1, FIG. 1 is a structure schematic view of an array substrate provided by one embodiment of the application. The array substrate provided by one embodiment of the application may include: a base plate 10, a buffer layer 20, a semiconductor layer 30, an insulation layer 40, and a grid layer 50. It should be noted that the array substrate provided in the embodiment of the application is not limited to this, for example, the array substrate can also include a source electrode, a drain electrode, etc.

Wherein, the base plate 10 is made of glass, quartz, sapphire, etc. It should be noted that materials of the base plate 10 include, but are not limited to, the above materials, and may also include other materials, which are not listed here.

Wherein, the buffer layer 20 is disposed on the base plate 10. In some embodiments, the buffer layer 20 is formed on the base plate 10 by chemical vapor deposition. Wherein, the buffer layer 20 may be a silicon oxide film (SiOx), a silicon nitride film (SiNx), or a composite film formed by alternating layers of a silicon oxide film and a silicon nitride film. In some embodiments, a thickness of the buffer layer 20 can be between 1000 Å-3000 Å.

Wherein, the semiconductor layer 30 is disposed on the buffer layer 20. In some embodiments, the semiconductor layer 30 is formed on the buffer layer 20 by physical vapor deposition. In some embodiments, the semiconductor layer 30 can be composed of polycrystalline silicon (POLY-Si).

In some embodiments, the semiconductor layer 30 may include a charge carrier channel 31. The charge carrier channel 31 can also be made of polycrystalline silicon. It should be noted that, elements doped in the polycrystalline silicon used in the charge carrier channel 31 is different from those doped in the polycrystalline silicon used in the rest of the semiconductor layer 30. A concentration of the doped elements in the charge carrier channel 31 is greater, but a concentration of the doped elements in the rest of the semiconductor layer 30 is less. In some embodiments, the doped elements may be boron, indium or gallium. The charge carrier channel 31 is mainly used to improve filling factor, short-circuit current and open-circuit voltage. In some embodiments, a thickness of the charge carrier channel 31 may be between 200 Å-500 Å.

Wherein, the insulation layer 40 is disposed on the semiconductor layer 30, and covers the buffer layer 20 and the semiconductor layer 30.

Wherein, the charge carrier channel 31 is located on one surface of the semiconductor layer 30 facing the insulation layer 40.

Wherein, the insulation layer 40 may include a first film layer 41 and a second film layer 42. The first film layer 41 covers the semiconductor layer 30 and the buffer layer 20. The second film layer 42 covers the first film layer 41. A density of the first film layer 41 is greater than that of the second film layer 42. Wherein, the first film layer 41 is connected with the charge carrier channel 31, the dense film can ensure the stability of the charge carrier channel 31.

It should be noted that in the description of this application, the terms “first” and “second” are used only for descriptive purposes and cannot be understood as indicating or implying relative importance or implying the number of technical features indicated. As a result, features defined as “first” and “second” can explicitly or implicitly include one or more of the said features.

It should be noted that, in the actual operation process, the densities of the first film layer 41 and the second film layer 42 are generally difficult to measure directly. Thus, the densities of the first film layer 41 and the second film layer 42 can be known by other means.

In some embodiments, during the deposition of the first film layer 41 and the second film layer 42, their approximate densities can be obtained by measuring their deposition rates. For example, the slower the deposition rate is, and the greater the density is. In some embodiments, the deposition rate of the first film layer is less than 15 Å/s, and the deposition rate of the second film layer is greater than or equal to 15 Å/s.

In some embodiments, the first film layer 41 and the second film layer 42 can also be etched with the same etching solution. Their approximate densities can be obtained by measuring their etching rates. For example, the slower the etching rate is, and the greater the density is. In some embodiments, the etching rate of the first film layer is between 150 nm/min-190 nm/min, and the etching rate of the second film layer is greater than 190 nm/min.

In the actual operation process, the cost of preparing compact films is high. For this reason, a thickness of the first film layer 41 is less than that of the second film layer 42 in order to save cost. A thickness of the first film layer is between 100 Å-200 Å, and a thickness of the second film layer is between 1200 Å-1500 Å.

In some embodiments, the first film layer 41 may include a first silicon oxide film, and the second film layer 42 may include a second silicon oxide film.

In some embodiments, the silicon oxide film is formed by chemical deposition, and silane and nitric oxide are used as reaction gases. In practical applications, a density of the silicon oxide film can be adjusted by changing deposition factors, such as the ratio or pressure of silane and nitric oxide.

Wherein, the grid layer 50 is disposed on the insulation layer 40. Namely, the grid layer 50 is formed on the second film layer 42. In some embodiments, a metal layer is formed on the insulation layer 40 by physical vapor deposition, and then is etched to form the grid layer 50. Wherein, the grid layer 50 is made of metals such as aluminum, molybdenum, copper or silver.

For the array substrate provided by the embodiment of the application, the insulation layer 40 includes the first film layer 41 with the higher density and the second film layer 42 with the lower density, and the thickness of the first film layer 41 is less than that of the second film layer 42, thereby saving the cost of fabricating the array substrate. Moreover, the array substrate provided in the embodiment of the application can ensure the stability of the charge carrier channel 31 by connecting the first film layer 41 with the higher density and the charge carrier channel 31, to improve the electrical stability of the array substrate.

Please refer to FIG. 2, the application further provides a method for manufacturing an array substrate in one embodiment. The specific process of the method includes as follows:

A step 101 is providing a base plate 10, and depositing a buffer layer 20 and a semiconductor layer 30 on the base plate 10 in turn.

A step 102 is disposing a charge carrier channel 31 on the semiconductor layer 30.

A step 103 is depositing an insulation layer 40 on the semiconductor layer 30.

Specifically, a first film layer 41 is deposited on the semiconductor layer 30 and covers the semiconductor layer 30 and the buffer layer 20; and a second film layer 42 is disposed on the first film layer 41. Wherein, a density of the first film layer 41 is greater than that of the second film layer 42.

A step 104 is depositing a grid layer 50 on the insulation layer 40.

It should be noted that, the array substrate manufactured by the method of the application has the same structure with the above array substrate, and the specific structure thereof may refer to the above embodiments and will not be described here.

In the above embodiments, description of each embodiment has its own emphasis, and the parts not detailed in one embodiment may be referred to in the relevant descriptions of other embodiments.

The above is a detailed description of the array substrate and the method for manufacturing the array substrate in the embodiment of the present application. In this paper, one specific example is used to illustrate the principle and implementation of this application. The illustration of the above embodiment is only used to help understand the technical scheme and its core ideas of this application. It should be understood by those skilled in the art that, they can still modify the technical schemes recorded in the foregoing embodiments or replace some of their technical features equally, and that these modifications or substitutions do not divert the essence of the corresponding technical schemes from the scope of the technical schemes of the embodiments of the present application.

What is claimed is:

1. An array substrate, including: a base plate, a buffer layer, a semiconductor layer, an insulation layer and a grid layer;
the buffer layer being disposed on the base plate;
the semiconductor layer being disposed on the buffer layer;
the insulation layer covering the buffer layer and the semiconductor layer; and
the grid layer being disposed on the insulation layer;
wherein, the semiconductor layer includes a charge carrier channel on one surface of the semiconductor layer facing the insulation layer; the insulation layer including a first film layer and a second film layer; the first film layer covering the semiconductor layer and the buffer layer; the second film layer covering the first film layer; the grid layer being located on the second film layer; a density of the first film layer being greater than that of the second film layer; the charge carrier channel being connected with the first film layer.

2. The array substrate as claimed in claim 1, wherein a thickness of the first film layer is between 100 Å-200 Å.

3. The array substrate as claimed in claim 1, wherein a deposition rate of the first film layer is less than 15 Å/s.

4. The array substrate as claimed in claim 1, wherein the first film layer includes a first silicon oxide film.

5. The array substrate as claimed in claim 1, wherein a thickness of the second film layer is between 1200 Å-1500 Å.

6. The array substrate as claimed in claim 1, wherein a deposition rate of the second film layer is greater than or equal to 15 Å/s.

7. The array substrate as claimed in claim 1, wherein the second film layer includes a second silicon oxide film.

8. The array substrate as claimed in claim 1, wherein a thickness of the charge carrier channel is between 200 Å-500 Å.

9. The array substrate as claimed in claim 1, wherein a material of the buffer layer includes silicon oxide, and a thickness of the buffer layer is between 2000 Å-3000 Å.

10. A method for manufacturing an array substrate, wherein, including:
providing a base plate, and depositing a buffer layer and a semiconductor layer on the base plate in turn;
disposing a charge carrier channel on the semiconductor layer;
depositing an insulation layer on the semiconductor layer, including
depositing a first film layer on the semiconductor layer, which covers the semiconductor layer and the buffer layer; and
depositing a second film layer on the first film layer, wherein, a density of the first film layer being greater than that of the second film layer;
depositing a grid layer on the insulation layer.

11. The method for manufacturing the array substrate as claimed in claim 10, wherein a thickness of the first film layer is between 100 Å-200 Å.

12. The method for manufacturing the array substrate as claimed in claim 10, wherein a deposition rate of the first film layer is less than 15 Å/s.

13. The method for manufacturing the array substrate as claimed in claim 10, wherein the first film layer includes a first silicon oxide film.

14. The method for manufacturing the array substrate as claimed in claim 10, wherein a thickness of the second film layer is between 1200 Å-1500 Å.

15. The method for manufacturing the array substrate as claimed in claim 10, wherein a deposition rate of the second film layer is greater than or equal to 15 Å/s.

16. The method for manufacturing the array substrate as claimed in claim 10, wherein the second film layer includes a second silicon oxide film.

17. The method for manufacturing the array substrate as claimed in claim 10, wherein a thickness of the charge carrier channel is between 200 Å-500 Å.

18. The method for manufacturing the array substrate as claimed in claim 10, wherein a material of the buffer layer includes silicon oxide, and a thickness of the buffer layer is between 2000 Å-3000 Å.
